(19) United States
(12) Patent Application Publication
(10) Pub. No.: US 2026/0110824 A1
(43) Pub. Date: Apr. 23, 2026

(54) ANTI-REFLECTIVE FILM, DISPLAY DEVICE INCLUDING THE SAME, AND ELECTRONIC DEVICE INCLUDING THE SAME

(71) Applicant: Samsung Display Co., LTD., Yongin-si (KR)

(72) Inventors: Hyeon Mi LEE, Yongin-si (KR); Da Hye KIM, Yongin-si (KR); Man Soo KIM, Yongin-si (KR); Jung Hyun KIM, Yongin-si (KR); Hyun Hyang KIM, Yongin-si (KR); Ju Young YOON, Yongin-si (KR)

(21) Appl. No.: 19/207,684

(22) Filed: May 14, 2025

(30) Foreign Application Priority Data
Oct. 18, 2024 (KR) 10-2024-0142742

(51) Int. Cl. G02B 1/115; G02B 1/14; H10K 59/80

(52) U.S. Cl. CPC G02B 1/115; G02B 1/14; H10K 59/879

(57) ABSTRACT

An anti-reflective film includes: a base film; first to sixth refractive layers sequentially stacked on the base film. A refractive index of the first refractive layer is greater than a refractive index of the second refractive layer, a refractive index of the third refractive layer is greater than a refractive index of the fourth refractive layer, a refractive index of the fifth refractive layer is greater than a refractive index of the sixth refractive layer, light is incident from an outside on a surface of the base film opposite to the first surface, the first refractive layer or the third refractive layer comprises oxynitride, and an oxygen content of the oxynitride is greater than 0 at % and equal to or less than 10 at %.

This application claims priority to Korean Patent Application No. 10-2024-0142742, filed on Oct. 18, 2024, and all the benefits accruing therefrom under 35 U.S.C. § 119, the content of which in its entirety is herein incorporated by reference.

### BACKGROUND

### 1. Field

The present disclosure relates to an anti-reflective film and a display device including the same.

### 2. Description of the Related Art

As the information society advances, the demand for display devices for displaying images is increasing in various forms. For example, display devices are applied to various electronic devices such as smartphones, digital cameras, laptop computers, navigation systems, and smart televisions.

In case that a display device is exposed to external light, such as various lighting sources or natural light, images created internally may not be clearly conveyed to the user due to reflected light, or may cause eye fatigue for the user. For this reason, the demand for anti-reflective properties is increasing.

### SUMMARY

Aspects of the present disclosure provide an anti-reflective film with enhanced hardness and durability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided an anti-reflective film including: a base film; a first refractive layer located on one surface of the base film; a second refractive layer located on the first refractive layer; a third refractive layer located on the second refractive layer; a fourth refractive layer located on the third refractive layer; a fifth refractive layer located on the fourth refractive layer; and a sixth refractive layer located on the fifth refractive layer, where a refractive index of the first refractive layer is greater than a refractive index of the second refractive layer, a refractive index of the third refractive layer is greater than a refractive index of the fourth refractive layer, a refractive index of the fifth refractive layer is greater than a refractive index of the sixth refractive layer, light is incident from the outside on the other surface of the base film, the first refractive layer or the third refractive layers includes oxynitride, and an oxygen content of the oxynitride is greater than 0 atomic percentages (at %) and equal to or less than 10 at %.

The first refractive layer or the third refractive layer may include: a second sub-layer containing oxynitride; and a first sub-layer located on the first sub-layer and containing a high-refractive-index material except for oxynitride.

The anti-reflective film may further include a third sub-layer located on the second sub-layer and containing a high-refractive-index material except for oxynitride.

The anti-reflective film may further a seventh refractive layer located on the sixth refractive layer; and an eighth refractive layer located on the seventh refractive layer, where a refractive index of the seventh refractive layer may be greater than a refractive index of the eighth refractive layer.

The oxynitride may include at least one of aluminum oxynitride, silicon oxynitride, aluminum-silicon oxynitride, germanium oxynitride, aluminum-germanium oxynitride, zirconium oxynitride, titanium oxynitride, and hafnium oxynitride.

In case that the oxynitride may be aluminum oxynitride, silicon oxynitride, or aluminum-silicon oxynitride, the oxygen content of the oxynitride may be greater than 0 at % and equal to or less than 5 at %.

In case that the oxynitride may be aluminum-germanium oxynitride, contents of aluminum, germanium, oxygen, and nitrogen in the aluminum-germanium oxynitride satisfy Equations 1 and 2:

$$0 < \frac{[ Ge ]}{[ Ge ] + [ Al ]} \leq 0.45 ; \qquad [ Equation 1 ]$$

$$0 < \frac{[ O ]}{[ O ] + [ N ]} \leq 0.3 , \qquad [ Equation 2 ]$$

where [Ge], [Al], [O], and [N] represent molar concentrations of germanium, aluminum, oxygen, and nitrogen, respectively.

The anti-reflective film may include a material with a refractive index of less than 1.6, and a weight ratio of the material with a refractive index of less than 1.6 may greater than 0 weight percentage (wt %) and less than 35 wt % with respect to a total weight of the anti-reflective film.

The anti-reflective film may have a hardness of at least 20 gigapascals (GPa) in case that a thickness of the anti-reflective film is from 50 nanometers (nm) to 600 nm.

The anti-reflective film may have a hardness of at least 20 GPa in case that a thickness of the anti-reflective film is from 600 nm to 800 nm.

The anti-reflective film may have a hardness of at least 22 GPa in case that a thickness of the anti-reflective film is from 800 nm to 1,000 nm.

According to an aspect of the present disclosure, there is provided an anti-reflective film including: a base film; a first refractive layer located on one surface of the base film; a second refractive layer located on the first refractive layer; a third refractive layer located on the second refractive layer; a fourth refractive layer located on the third refractive layer; a fifth refractive layer located on the fourth refractive layer; and a sixth refractive layer located on the fifth refractive layer, where a refractive index of the first refractive layer is greater than a refractive index of the second refractive layer, a refractive index of the third refractive layer is greater than a refractive index of the fourth refractive layer, a refractive index of the fifth refractive layer is greater than a refractive index of the sixth refractive layer, light is incident from the outside on the other surface of the base film, the first refractive layer or the third refractive layer includes: a first sub-layer; a second sub-layer located on the first sub-layer; and a third sub-layer located on the second sub-layer, the first and third sub-layers each independently include oxide or nitride, the second sub-layer includes oxynitride, and an oxygen content of the oxynitride may be greater than 0 at % and equal to or less than 10 at %.

The oxynitride may include aluminum oxynitride, silicon oxynitride, aluminum-silicon oxynitride, germanium oxynitride, aluminum-germanium oxynitride, zirconium oxynitride, titanium oxynitride, or hafnium oxynitride.

The first sub-layer and the third sub-layer each independently may include at least one element selected from aluminum, silicon, germanium, zirconium, titanium, and hafnium, and the second sub-layer may further include the elements present in both the first sub-layer and the third sub-layer.

The anti-refractive film may further include: a seventh refractive layer located on the sixth refractive layer, and an eighth refractive layer located on the seventh refractive layer, where a refractive index of the seventh refractive layer may be greater than a refractive index of the eighth refractive layer.

The anti-reflective film may include a material with a refractive index of less than 1.6, and a weight ratio of the material with a refractive index of less than 1.6 is greater than 0 wt % and less than 35 wt % with respect to a total weight of the anti-reflective film.

The anti-reflective film may have a hardness of at least 20 GPa in case that a thickness of the anti-reflective film may be from 50 nm to 600 nm.

According to an aspect of the present disclosure, there is provided a display device film including: a display panel; an anti-reflective film located on the display panel; and a window member located on the anti-reflective film, where the anti-reflective film includes: a base film; a first refractive layer located on one surface of the base film; a second refractive layer located on the first refractive layer; a third refractive layer located on the second refractive layer; a fourth refractive layer located on the third refractive layer; a fifth refractive layer located on the fourth refractive layer; and a sixth refractive layer located on the fifth refractive layer, a refractive index of the first refractive layer is greater than a refractive index of the second refractive layer, a refractive index of the third refractive layer is greater than a refractive index of the fourth refractive layer, a refractive index of the fifth refractive layer is greater than a refractive index of the sixth refractive layer, the window member is located on the other surface of the base film, the first refractive layer or the third refractive layer includes an oxynitride, and an oxygen content of the oxynitride is greater than 0 at % and equal to or less than 10 at %.

The first refractive layer or the third refractive layer may include: a first sub-layer containing the oxynitride, and a second sub-layer located on the first sub-layer and containing a high-refractive-index material.

The first refractive layer or the third refractive layer may include: a first sub-layer; a second sub-layer located on the first sub-layer; and a third sub-layer located on the second sub-layer, the first and third sub-layers each independently may include an oxide or a nitride, and the second sub-layer includes an oxynitride.

According to an aspect of the present disclosure, there is provided an electronic device including: a display device for providing an image; and a processor for transmitting an image data signal to the display device, and the display device, wherein the display device including: a display panel; an anti-reflective film located on the display panel; and a window member located on the anti-reflective film, wherein the anti-reflective film may include: a base film; a first refractive layer located on one surface of the base film; a second refractive layer located on the first refractive layer; a third refractive layer located on the second refractive layer; a fourth refractive layer located on the third refractive layer; a fifth refractive layer located on the fourth refractive layer; and a sixth refractive layer located on the fifth refractive layer, a refractive index of the first refractive layer may be greater than a refractive index of the second refractive layer, a refractive index of the third refractive layer may be greater than a refractive index of the fourth refractive layer, a refractive index of the fifth refractive layer may be greater than a refractive index of the sixth refractive layer, the window member is located on the other surface of the base film, the first refractive layer or the third refractive layer comprises an oxynitride, and an oxygen content of the oxynitride is greater than 0 at % and equal to or less than 10 at %.

The anti-reflective film according to the present invention achieves improved hardness and durability by positioning refractive layers containing an oxynitride with low oxygen content as its upper layers.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a display device according to an embodiment;

FIG. 2 is an exploded perspective view of the display device according to an embodiment;

FIG. 3 is a side view of the display device according to an embodiment;

FIG. 4 is a schematic cross-sectional view of a display panel according to an embodiment;

FIG. 5 is a diagram illustrating a first example of an anti-reflective film in the display device according to an embodiment;

FIG. 6 is a diagram illustrating structural changes in accordance with oxygen content in nitrides;

FIG. 7 is a diagram illustrating a second example of the anti-reflective film in the display device according to an embodiment;

FIG. 8 is a cross-sectional view illustrating a first example of a refractive layer of the anti-reflective film in the display device according to an embodiment;

FIG. 9 is a cross-sectional view illustrating a second example of the refractive layer of the anti-reflective film in the display device according to an embodiment;

FIG. 10 is a cross-sectional view illustrating a third example of the refractive layer of the anti-reflective film in the display device according to an embodiment;

FIG. 11 is a graph showing the hardness (GPa) of Embodiment 1 and Comparative Example 1 as a function of indentation depth (nm);

FIG. 12 is a graph showing the hardness (GPa) of Embodiment 2 and Comparative Example 2 as a function of indentation depth (nm);

FIG. 13 is a graph showing the hardness (GPa) of Embodiment 3 and Comparative Example 3 as a function of indentation depth (nm);

FIG. 14 is a graph showing the hardness (GPa) of Embodiments 1 through 3 and Comparative Example 7 as a function of indentation depth (nm);

FIG. 15 is a graph showing the hardness (GPa) of Embodiment 4 and Comparative Example 4 as a function of indentation depth (nm);

FIG. 16 is a graph showing the hardness (GPa) of Embodiment 5 and Comparative Example 5 as a function of indentation depth (nm);

FIG. 17 is a graph showing the hardness (GPa) of Embodiment 6 and Comparative Example 6 as a function of indentation depth (nm); and

FIG. 18 is a graph showing the hardness (GPa) of Embodiments 4 through 6 and Comparative Example 7 as a function of indentation depth (nm).

### DETAILED DESCRIPTION

The advantages and features of the present invention, and the methods for achieving them, will become clear with reference to the embodiments described below in detail with the accompanying drawings. However, the present invention is not limited to the embodiments disclosed below, but may be implemented in various different forms, and these embodiments are provided only to make the disclosure of the present invention complete and to fully inform those skilled in the art of the invention of the scope of the invention, and the present invention is defined only by the scope of the claims.

In case that elements or layers are referred to as “on” another element or layer, this includes all cases where another layer or another element is interposed directly over or in the middle of the other element. The same reference numerals refer to the same components throughout the specification. The shapes, sizes, ratios, angles, numbers, etc. disclosed in the drawings for explaining the embodiments are examples, and therefore the present invention is not limited to the matters illustrated.

Although the terms “first” and “second” are used to describe various components, these components are not limited by these terms. These terms are only used to distinguish one component from another. Therefore, it goes without saying that the first component mentioned below may be the second component within the technical idea of the present invention.

Each of the features of the various embodiments of the present invention may be partially or wholly combined or combined with each other, and various technical connections and operations are possible, and each embodiment may be implemented independently of each other or may be implemented together in a related relationship.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Specific embodiments will be described below with reference to the attached drawings.

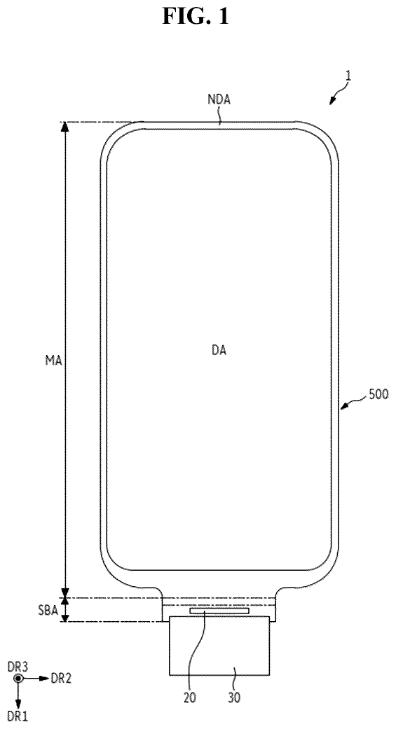

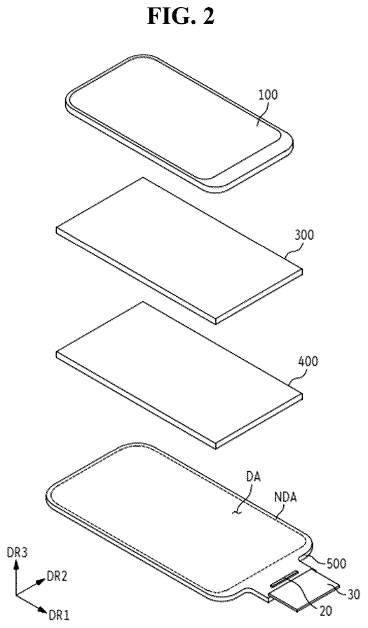

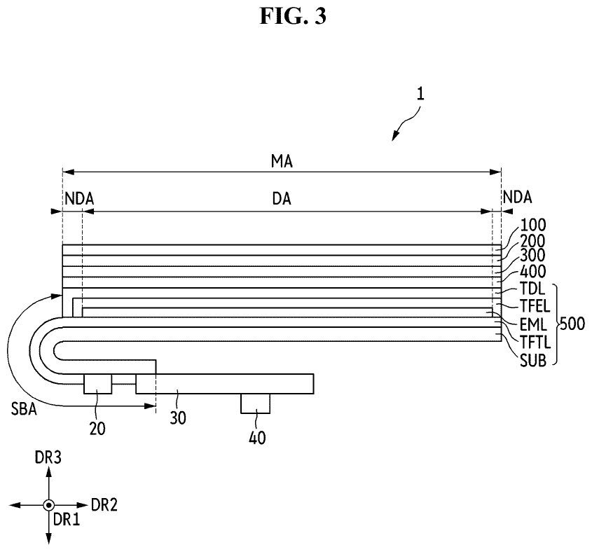

FIG. 1 is a plan view of a display device according to an embodiment. FIG. 2 is an exploded perspective view of the display device according to an embodiment. FIG. 3 is a side view of the display device according to an embodiment.

Referring to FIGS. 1 through 3, a display device 1 may include a window member 100, an adhesive member 200, a fingerprint-resistant film 300, an anti-reflective film 400, and a display panel 500.

The display device 1 is a device that displays moving or still images and may be used as a display screen for various products, including portable electronic devices such as mobile phones, smartphones, tablet PCs, smartwatches, watch phones, mobile communication terminals, electronic notebooks, e-book readers, portable multimedia players, navigation systems, Ultra Mobile PCs (UMPCs), as well as televisions, laptops, monitors, advertising displays, and Internet of Things (IoT) devices.

The display device 1 may be a light-emitting display device, such as an organic light-emitting display device using organic light-emitting diodes (OLEDs), a quantum dot light-emitting display device containing a quantum dot emission layer, an inorganic light-emitting display device containing inorganic semiconductors, or a micro- or nano-light-emitting display device using micro- or nano-light-emitting diodes (LEDs). The display device 1 will hereinafter be described as being an organic light-emitting display device, but the present disclosure is not limited thereto.

The display device 1 includes a display panel 500, a display driving circuit 20, and a circuit board 30.

The display panel 500 may be formed as a rectangular plane with short sides in a first direction DR1 and long sides in a second direction DR2 intersecting the first direction DR1. The display panel 500 may also have a thickness in a third direction DR3 intersecting both the first and second directions DR1 and DR2. The corners where the short sides in the first direction DR1 and the long sides in the second direction DR2 meet may be rounded with a predetermined curvature or may be formed at a right angle. The planar shape of the display panel 500 is not limited to a rectangle and may be formed as another polygon, a circle, or an ellipse. The display panel 500 may be formed flat but is not limited thereto. For example, the display panel 500 may include curved sections formed at the left and right ends with a constant or varying curvature. Additionally, the display panel 500 may be flexibly formed to be bendable, curvable, foldable, or rollable.

The display panel 500 may include a main area MA and a sub-area SBA.

The main area MA may include a display area DA for displaying images and a non-display area NDA surrounding the display area DA. The display area DA may occupy most of the main area MA. The display area DA may be located at the center of the main area MA. The non-display area NDA may be located adjacent to the display area DA. The non-display area NDA may be the outer area of the display area DA. The non-display area NDA may be located to surround the display area DA. The non-display area NDA may be the edge area of the display panel 500.

The sub-area SBA may extend in the first direction DR1 from one side of the main area MA. The length of the sub-area SBA in the first direction DR1 may be smaller than the length of the main area MA in the first direction DR1. The length of the sub-area SBA in the second direction DR2 may be smaller than or substantially equal to the length of the main area MA in the second direction DR2. The sub-area SBA may be bent and located below the display panel 500. In this case, the sub-area SBA may overlap with the main area MA in the third direction DR3.

The display driving circuit 20 may generate signals and voltages for driving the display panel 500. The display driving circuit 20 may be formed as an integrated circuit (IC) and attached to the sub-area SBA of the display panel 500 by a chip-on-glass (COG) method, a chip-on-plastic (COP) method, or an ultrasonic bonding method. Alternatively, the display driving circuit 20 may be attached to the circuit board 30 by a chip-on-film (COF) method.

The circuit board 30 may be attached to one end of the sub-area SBA of the display panel 500. As a result, the circuit board 30 may be electrically connected to the display panel 500 and the display driving circuit 20. The display panel 500 and the display driving circuit 20 may receive digital video data, timing signals, and drive voltages via the circuit board 30. The circuit board 30 may be a flexible printed circuit board (FPCB), a printed circuit board (PCB), or a flexible film such as a COF.

The window member 100 may be attached to the front surface of the fingerprint-resistant film 300 by the adhesive member 200. The window member 100 may include a transparent material, such as glass or plastic. For example, the window member 100 may be ultra-thin glass (“UTG”) with a thickness of greater than 0 millimeters (mm) and equal to or less than 0.1 mm or a transparent polyimide (“PI”) film.

The adhesive member 200 may be a transparent adhesive film or a transparent adhesive resin. For example, the adhesive member 200 may include a transparent adhesive such as a pressure-sensitive adhesive (“PSA”) or an optically clear adhesive (“OCA”). The adhesive member 200 may include an acrylic-based adhesive material.

The fingerprint-resistant film 300 may be located on the front surface of the window member 100. The fingerprint-resistant film 300 may prevent the fingerprints of a user from adhering to the display device 1.

The anti-reflective film 400 may be located on the front surface of the display panel 500. The anti-reflective film 400 may include a plurality of refractive layers with different refractive indices. The anti-reflective film 400 can reduce reflected light through the refractive layers. The anti-reflective film 400, which is a key feature of the present disclosure, will be described later in detail.

The display device 1 may further include, below the display panel 500, a light-shielding layer (not illustrated) to absorb light incident from the outside, a buffer layer (not illustrated) to absorb external impacts, and a heat-dissipating layer (not illustrated) for efficient heat dissipation of the display panel 500.

The light-shielding layer may block light transmission to prevent the components located below the light-shielding layer from being visible from the top of the display panel 500. The light-shielding layer may include a light-absorbing material such as black pigment or black dye.

The buffer layer may absorb external impacts to prevent damage to the display panel 500. The buffer layer may be formed as a single layer or multiple layers. For example, the buffer layer may include a polymer resin such as polyurethane, polycarbonate, polypropylene, or polyethylene, or may include an elastic material such as foam-molded sponge formed from rubber, a urethane-based material, or an acrylic-based material.

The heat-dissipating layer may include a first heat-dissipating layer containing a material such as graphite or carbon nanotubes, and a second heat-dissipating layer formed as a thin metal film with excellent thermal conductivity and electromagnetic wave shielding properties, including a metal such as copper, nickel, ferrite, or silver.

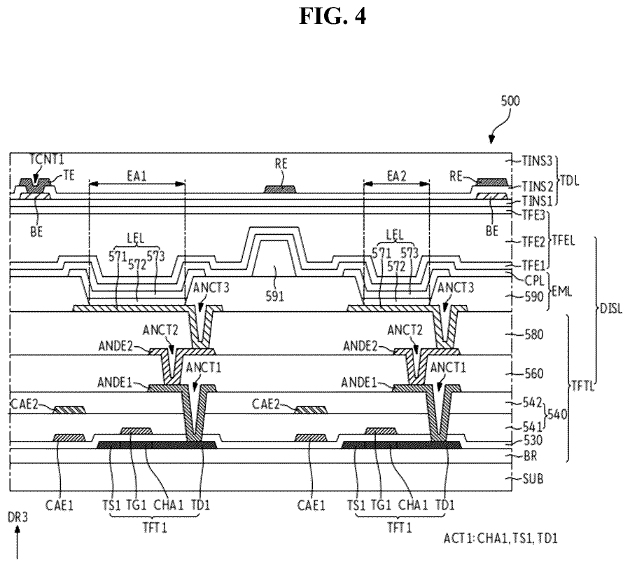

FIG. 4 is a schematic cross-sectional view of a display panel according to an embodiment.

Referring to FIG. 4, a display panel 500 may include a substrate SUB, a display layer DISL located on the substrate SUB, and a touch detection layer TDL located on the display layer DISL. The display layer DISL may include a thin film transistor layer TFTL, a light-emitting element layer EML, and an encapsulation layer TFEL.

A thin film transistor layer TFTL may be located on the substrate SUB. The thin film transistor layer TFTL may include a barrier film BR, thin film transistors TFT1, first capacitor electrodes CAE1, second capacitor electrodes CAE2, first anode connection electrodes ANDE1, second anode connection electrodes ANDE2, a gate insulating film 530, a first interlayer insulating film 541, a second interlayer insulating film 542, a first planarization film 560, and a second planarization film 580.

The substrate SUB may include an insulating material such as a polymer resin. For example, the substrate SUB may include polyimide. The substrate SUB may be a flexible substrate capable of bending, folding, or rolling.

The barrier film BR may be located on the substrate SUB. The barrier film BR protects the thin film transistors TFT1 in the thin film transistor layer TFTL and emission layers 572 of the light-emitting element layer EML from moisture that may penetrate through the moisture-sensitive substrate SUB. The barrier film BR may include a plurality of inorganic films alternately stacked. For example, the barrier film BR may be in a multi-layer structure with one or more inorganic films selected from a silicon nitride layer, a silicon oxynitride layer, a silicon oxide layer, a titanium oxide layer, and an aluminum oxide layer.

The thin film transistors TFT1 may be located on the barrier film BR. An active layer ACT1 of the thin film transistors TFT1 may be located on the barrier film BR. The active layer ACT1 may include polycrystalline silicon, monocrystalline silicon, low-temperature polycrystalline silicon, amorphous silicon, or an oxide semiconductor.

The active layer ACT1 may include channel regions CHA1, source regions TS1, and drain regions TD1. The channel regions CHA1 may overlap with gate electrodes TG1 in the thickness direction of the substrate SUB, i.e., in the third direction DR3. The source regions TS1 may be located on first sides of the channel regions CHA1, and the drain regions TD1 may be located on second sides of the channel regions CHA1. The source regions TS1 and the drain regions TD1 may be regions that do not overlap with the gate electrodes TG1 in the third direction DR3. The source regions TS1 and the drain regions TD1 may be regions with conductivity, formed by doping a silicon semiconductor or an oxide semiconductor with ions or impurities.

A gate insulating film 530 may be located on the active layer ACT1. The gate insulating film 530 may be an inorganic film, such as a silicon nitride layer, a silicon oxynitride layer, a silicon oxide layer, a titanium oxide layer, or an aluminum oxide layer.

The gate electrodes TG1 of the thin film transistors TFT1 and the first capacitor electrodes CAE1 may be located on the gate insulating film 530. The gate electrodes TG1 may overlap with the channel regions CHA1 in the third direction DR3. In FIG. 4, the gate electrodes TG1 and the first capacitor electrodes CAE1 are illustrated as being separated, but may be connected and formed integrally. The gate electrodes TG1 and the first capacitor electrodes CAE1 may be formed as single or multi-layer structures containing one of molybdenum (Mo), aluminum (Al), chromium (Cr), gold (Au), titanium (Ti), nickel (Ni), neodymium (Nd), copper (Cu), or an alloy thereof.

A first interlayer insulating film 541 may be located on the gate electrodes TG1 and the first capacitor electrodes CAE1 of the thin film transistors TFT1. The first interlayer insulating film 541 may be an inorganic film, such as a silicon nitride layer, a silicon oxynitride layer, a silicon oxide layer, a titanium oxide layer, or an aluminum oxide layer. The first interlayer insulating film 541 may include a plurality of inorganic films.

The second capacitor electrodes CAE2 may be located on the first interlayer insulating film 541. The second capacitor electrodes CAE2 may overlap with the first capacitor electrodes CAE1 of the thin film transistors TFT1 in the third direction DR3. Additionally, in case that the gate electrodes TG1 and the first capacitor electrodes CAE1 are formed integrally, the second capacitor electrodes CAE2 may overlap with the gate electrodes TG1 in the third direction DR3. Since the first interlayer insulating film 541 has a predetermined dielectric constant, capacitors may be formed by the first capacitor electrodes CAE1, the second capacitor electrodes CAE2, and the first interlayer insulating film 541 located between the first capacitor electrodes CAE1 and the second capacitor electrodes CAE2. The second capacitor electrodes CAE2 may be single or multi-layer structures of one of Mo, Al, Cr, Au, Ti, Ni, Nd, Cu, or an alloy thereof.

The second interlayer insulating film 542 may be located on the second capacitor electrodes CAE2. The second interlayer insulating film 542 may be an inorganic film, such as a silicon nitride layer, a silicon oxynitride layer, a silicon oxide layer, a titanium oxide layer, or an aluminum oxide layer. The second interlayer insulating film 542 may include of a plurality of inorganic films.

The first anode connection electrodes ANDE1 may be located on the second interlayer insulating film 542. The first anode connection electrodes ANDE1 may be connected to the drain regions TD1 of the thin film transistors TFT1 through first connection contact holes ANCT1, which pass through the gate insulating film 530, the first interlayer insulating film 541, and the second interlayer insulating film 542. The first anode connection electrodes ANDE1 may be single or multi-layer structures of one of Mo, Al, Cr, Au, Ti, Ni, Nd, Cu, or an alloy thereof.

The first planarization film 560 may be located on the first anode connection electrodes ANDE1 to planarize the step caused by the thin film transistors TFT1. The first planarization film 560 may be formed as an organic film from a material such as an acrylic resin, epoxy resin, phenolic resin, polyamide resin, or polyimide resin.

The second anode connection electrodes ANDE2 may be located on the first planarization film 560. The second anode connection electrodes ANDE2 may be connected to the first anode connection electrodes ANDE1 through second connection contact holes ANCT2 that penetrate the first planarization film 560. The second anode connection electrodes ANDE2 may be formed as single-layer or multi-layer structures of one of Mo, Al, Cr, Au, Ti, Ni, Nd, Cu, or an alloy thereof.

The second planarization film 580 may be located on the second anode connection electrodes ANDE2. The second planarization film 580 may be formed as an organic film from a material such as an acrylic resin, epoxy resin, phenolic resin, polyamide resin, or polyimide resin.

The light-emitting element layer EML, including light-emitting elements LEL and a bank 590, may be located on the second planarization film 580. Each of the light-emitting elements LEL may include a pixel electrode 571, an emission layer 572, and a common electrode 573.

The pixel electrodes 571 may be located on the second planarization film 580. The pixel electrodes 571 may be connected to the second anode connection electrodes ANDE2 through third connection contact holes ANCT3 that penetrate the second planarization film 580.

In a top emission structure, where light is emitted toward the common electrodes 573 with respect to the emission layers 572, the pixel electrodes 571 may include a high-reflectance metal material such as a laminated structure of titanium/aluminum/titanium (Ti/Al/Ti), indium tin oxide/aluminum/indium tin oxide (ITO/AI/ITO), indium tin oxide/silver/indium tin oxide (ITO/Ag/ITO), a silver-palladium-copper (APC) alloy, or a laminated structure of an APC alloy and indium tin oxide (ITO/APC/ITO).

The bank 590 may be formed on the second planarization film 580 to partition the pixel electrode 571, thereby defining emission parts (EA1 and EA2). The bank 590 may be located to cover the edges of the pixel electrode 571. The bank 590 may be formed as an organic film from a material such as an acrylic resin, epoxy resin, phenolic resin, polyamide resin, or polyimide resin.

First emission parts EA1 and second emission parts EA2 may include the pixel electrodes 571, the emission layers 572, and the common electrodes 573 that are sequentially stacked, and represent regions where holes from the pixel electrodes 571 and electrons from the common electrodes 573 recombine in the emission layers 572 to emit light.

The emission layers 572 may be located on the pixel electrodes 571 and the bank 590. The emission layers 572 may include an organic material that emits a predetermined color of light. For example, the emission layers 572 may include hole transport layers, organic material layers, and electron transport layers.

The common electrodes 573 may be located on the emission layers 572. The common electrodes 573 may be located to cover the emission layers 572. The common electrodes 573 may be common layers formed over both the first emission parts EA1 and the second emission parts EA2.

In the top emission structure, the common electrodes 573 may be formed from a transparent conductive oxide (TCO), such as indium tin oxide (ITO) or indium zinc oxide (IZO), or a semi-transmissive conductive material, such as Mg, Ag, or an alloy of Mg and Ag. In case that the common electrodes 573 are formed from a semi-transmissive conductive material, light extraction efficiency may be enhanced by a micro-cavity effect.

A spacer 591 may be located on the bank 590. The spacer 591 may support a mask during the manufacture of the emission layers 572. The spacer 591 may be formed as an organic film from a material such as an acrylic resin, epoxy resin, phenolic resin, polyamide resin, or polyimide resin.

In some embodiments, the display panel 500 may further include a capping layer CPL located on the common electrodes 573. The capping layer CPL may include an inorganic material. For example, the capping layer CPL may include at least one material selected from silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

An encapsulation layer TFEL may be located on the common electrodes 573. The encapsulation layer TFEL may include at least one inorganic film to prevent oxygen or moisture from penetrating the light-emitting element layers EML. Additionally, the encapsulation layer TFEL may include at least one organic film to protect the light-emitting element layers EML from contaminants such as dust. For example, the encapsulation layer TFEL may include a first encapsulation inorganic film TFE1, an encapsulation organic film TFE2, and a second encapsulation inorganic film TFE3.

The first encapsulation inorganic film TFE1 may be located on the common electrodes 573, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be multi-layer structures formed by alternately stacking one or more inorganic films selected from silicon nitride, silicon oxynitride, silicon oxide, titanium oxide, and aluminum oxide layers. The encapsulation organic film TFE2 may be an organic film, such as an acrylic resin, epoxy resin, phenolic resin, polyamide resin, or polyimide resin.

The touch detection layer TDL may be located on the encapsulation layer TFEL. The touch detection layer TDL may include a first touch insulating film TINS1, connection electrodes BE, a second touch insulating film TINS2, driving electrodes TE, sensing electrodes RE, and a third touch insulating film TINS3.

The first touch insulating film TINS1 may be located on the encapsulation layer TFEL. The first touch insulating film TINS1 may be an inorganic film, such as a silicon nitride layer, a silicon oxynitride layer, a silicon oxide layer, a titanium oxide layer, or an aluminum oxide layer.

The connection electrodes BE may be located on the first touch insulating film TINS1. The connection electrodes BE may be formed as single-layer or multi-layer structures of one of Mo, Al, Cr, Au, Ti, Ni, Nd, Cu, and an alloy thereof.

The second touch insulating film TINS2 may be located on the connection electrodes BE. The second touch insulating film TINS2 may be an inorganic film, such as a silicon nitride layer, a silicon oxynitride layer, a silicon oxide layer, a titanium oxide layer, or an aluminum oxide layer. Alternatively, the second touch insulating film TINS2 may be formed as an organic film from a material such as an acrylic resin, epoxy resin, phenolic resin, polyamide resin, or polyimide resin.

The driving electrodes TE and the sensing electrodes RE may be located on the second touch insulating film TINS2. The driving electrodes TE and the sensing electrodes RE may be formed as single-layer or multi-layer structures of one of Mo, Al, Cr, Au, Ti, Ti, Ni, Nd, Cu, and an alloy thereof.

The driving electrodes TE and the sensing electrodes RE may overlap with the connection electrodes BE in the third direction DR3. The driving electrodes TE may be connected to the connection electrodes BE through touch contact holes TCNT1 that pass through the first touch insulating film TINS1.

The third touch insulating film TINS3 may be formed on the driving electrodes TE and the sensing electrodes RE. The third touch insulating film TINS3 may serve to planarize the step created by the driving electrodes TE, the sensing electrodes RE, and the connection electrodes BE. The third touch insulating film TINS3 may be formed as an organic film using a material such as an acrylic resin, epoxy resin, phenolic resin, polyamide resin, or polyimide resin.

Various embodiments of the anti-reflective film 400, which is a key feature of the display device 1, will hereinafter be described.

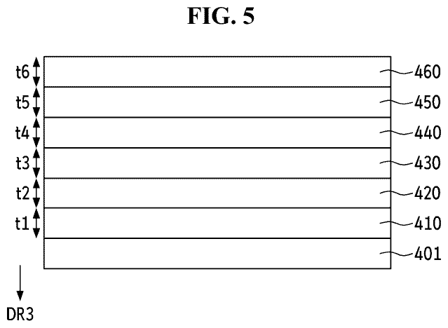

FIG. 5 is a diagram illustrating a first example of the anti-reflective film in the display device according to an embodiment.

Referring to FIG. 5, the anti-reflective film 400 may include a base film 401, a first refractive layer 410, a second refractive layer 420, a third refractive layer 430, a fourth refractive layer 440, a fifth refractive layer 450, and a sixth refractive layer 460.

The refractive index of the first refractive layer 410 may be greater than the refractive index of the second refractive layer 420. The refractive index of the third refractive layer 430 may be greater than the refractive index of the fourth refractive layer 440. The refractive index of the fifth refractive layer 450 may be greater than the refractive index of the sixth refractive layer 460. The first, third, and fifth refractive layers 410, 430, and 440 may correspond to relatively high-refractive-index layers, and the second, fourth, and sixth refractive layers 420, 440, and 460 may correspond to relatively low-refractive-index layers. The refractive index of the first, third, and fifth refractive layers 410, 430, and 440 may range from 1.70 to 2.80, but is not limited thereto. The refractive index of the second, fourth, and sixth refractive layers 420, 440, and 460 may range from 1.20 to 1.60, but is not limited thereto.

The low-refractive-index layers 420, 440, and 460 may include at least one of silicone resin, silica, and silicon dioxide (SiO₂), but are not limited thereto. Additionally, the low-refractive-index layers 420, 440, and 460 may include any material suitable for achieving a low refractive index.

The anti-reflective film 400 may include a material with a refractive index of less than 1.6, and the weight ratio of the material with a refractive index of less than 1.6 may be less than 35 wt % with respect to a total weight of the anti-reflective film 400.

The anti-reflective film 400 may include a material with a refractive index of greater than 1.7, and the weight ratio of the material with a refractive index of greater than 1.7 may be at least 65 wt % with respect to a total weight of the anti-reflective film 400.

As the high-refractive-index material with a refractive index of greater than 1.7 is contained in the anti-reflective film 400 at a weight ratio of at least 65 wt %, the hardness of the anti-reflective film 400 can be increased.

Thicknesses t₁, t₂, t₃, t₄, t₅, and to of the first, second, third, fourth, fifth, and sixth refractive layers 410, 420, 430, 440, 450, and 460 may be the same or different. The thicknesses t₁, t₂, t₃, t₄, t₅, and t₆ of the first, second, third, fourth, fifth, and sixth refractive layers 410, 420, 430, 440, 450, and 460 may be determined based on characteristics such as the target reflection wavelength, hardness, durability, and reflectance of the anti-reflective film 400.

The thicknesses t₁, t₂, t₃, t₄, t₅, and t₆ of the first, second, third, fourth, fifth, and sixth refractive layers 410, 420, 430, 440, 450, and 460 may be calculated as shown in Equation 3 below:

$$t = \frac{λ}{4 n} \qquad [ Equation 3 ]$$

In Equation 3, t denotes the thickness t₁, t₂, t₃, t₄, t₅, or to of the first, second, third, fourth, fifth, or sixth refractive layer 410, 420, 430, 440, 450, or 460 in the anti-reflective film 400, λ denotes the target reflection wavelength of the anti-reflective film 400, and n denotes the refractive index of the first, second, third, fourth, fifth, or sixth refractive layer 410, 420, 430, 440, 450, or 460.

For example, if the target reflection wavelength of the anti-reflective film 400 is 500 nm and the refractive index of the first refractive layer 410 is 2.3, the thickness may be approximately 54 nm. Alternatively, if the target reflection wavelength of the anti-reflective film 400 is 500 nm and the refractive index of the second refractive layer 420 is 1.2, the thickness may be approximately 104 nm.

Generally, a high-refractive-index layer has a greater hardness than a low-refractive-index layer, and to enhance the durability of the anti-reflective film 400, the hardness of the high-refractive-index layer may be improved.

Nitrides, due to their high refractive index and hardness characteristics, may primarily be used as high-refractive-index layers. To form nitrides, high-purity nitrogen and inert gas need to be introduced. If moisture or oxygen is incorporated during the formation of nitrides, oxynitrides, which generally exhibit lower hardness and refractive indices than nitrides, may be generated. To prevent decreases in hardness and refractive index caused by moisture or oxygen incorporation, strict process control, such as managing the chamber environment and injection gases, may be required, which can increase processing cost.

However, some nitrides may retain high refractive index and hardness characteristics even in case that they form oxynitrides upon reacting with a small amount of oxygen.

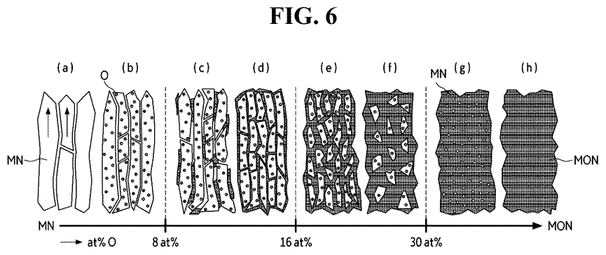

FIG. 6 illustrates structural changes in accordance with oxygen content in nitrides.

(a) of FIG. 6 shows the structure of a nitride MN without oxygen content. (b) of FIG. 6 shows the structure of an oxynitride MON with an oxygen content of 8 at % or less. Referring to (b) of FIG. 6, it can be observed that in case that the oxygen content of the oxynitride MON is 8 at % or less, only minor microstructural changes occur within the crystal structure of the nitride MN, while the overall crystal structure of the nitride MN remains largely unchanged. In other words, compared to the nitride MN, the oxynitride MON with an oxygen content of 8 at % or less undergoes only microstructural changes with minimal overall changes in its crystal structure. Thus, the refractive index and hardness of the oxynitride MON may be similar to the refractive index and hardness of the nitride MN. Here, “M” is an element or combination of elements for example, Al, Si, Ge, Zr, Ti, Hf, etc.

Referring to (c) through (f) of FIG. 6, it can be seen that in case that the oxygen content of the oxynitride MON is between 8 at % and 30 at %, the oxynitride MON undergoes changes not only in its microstructure but also in the overall crystal structure, transforming into an amorphous structure.

Referring to (g) and (h) of FIG. 6, it can be observed that in case that the oxygen content of the oxynitride MON is 30 at % or higher, the oxynitride MON changes into an amorphous structure.

An oxynitride MON with an oxygen content of greater than 0 at % and equal to or less than 10 at % has a structure similar to a structure of the nitride MN and can maintain high refractive index and high strength characteristics.

To form the nitride MN, it is desirable to block moisture or oxygen, requiring strict process control of the chamber environment and injection gases. In contrast, for the oxynitride MON, which is generated in the presence of moisture or oxygen, process control may be easier compared to forming the nitride MN. An oxynitride MON with an oxygen content of greater than 0 at % and equal to or less than 10 at % has a structure similar to a structure of the nitride MN, thereby largely maintaining the high refractive index and high strength characteristics of the nitride MN.

In summary, an oxynitride MON with an oxygen content of greater than 0 at % and equal to or less than 10 at % can maintain the high refractive index and high strength characteristics of the nitride MN while also simplifying the process and reducing manufacturing cost. Furthermore, the hardness of the first and third refractive layers 410 and 430 containing the oxynitride MON with an oxygen content of greater than 0 at % and equal to or less than 10 at % may be greater than the hardness of refractive layers containing the nitride MN, not oxynitride MON.

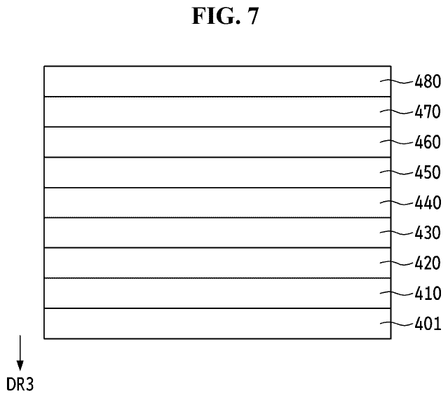

FIG. 7 is a diagram illustrating a second example of the anti-reflective film in the display device according to an embodiment.

The anti-reflective film 400 may include a base film 401, a first refractive layer 410 located on one surface of the base film 401, a second refractive layer 420 located on the first refractive layer 410, a third refractive layer 430 located on the second refractive layer 420, a fourth refractive layer 440 located on the third refractive layer 430, a fifth refractive layer 450 located on the fourth refractive layer 440, and a sixth refractive layer 460 located on the fifth refractive layer 450, and light may be incident on the other surface of the base film 401 from the outside.

The anti-reflective film 400 may be provided as a multi-layer structure by alternately stacking high-refractive-index and low-refractive-index layers using the characteristics of a distributed Bragg reflector (“DBR”). The anti-reflective film 400 is illustrated as having the first, second, third, fourth, fifth, sixth, seventh, and eighth refractive layers 410, 420, 430, 440, 450, 460, 470, and 480 stacked therein. Alternatively, the anti-reflective film 400 may be provided as a multi-layer structure by alternating stacking the high-refractive-index layers 410, 430, 450, and 470 and the low-refractive-index layers 420, 440, 460, and 480.

In the anti-reflective film 400, refractive layers close to the base film 401 in the third direction DR3, such as the first, second, third, and fourth refractive layers 410, 420, 430, and 440, may be defined as “upper layers”, and refractive layers farther from the base film 401 in the third direction DR3, such as the fifth, sixth, seventh, and eighth refractive layers 450, 460, 470, and 480, may be defined as “lower layers”. The anti-reflective film 400 is illustrated as including eight reflective layers, but is not limited thereto. For example, if the anti-reflective film 400 has n layers (where n is an integer), (n−3)-th through n-th layers may be considered as lower layers. The lower layers of the anti-reflective film 400 may refer to the refractive layers farther from the base film 401 in the third direction DR3.

In the display device 1, the lower layers of the anti-reflective film 400 may be located to face the display panel 500, and the upper layers of the anti-reflective film 400 may be located to face the window member 100.

In the display device 1, the first refractive layer 410 may be located on one surface of the base film 401, and the window member 100 may be located on the other surface of the base film 401.

In case that incident light from the outside or pressure is applied to the anti-reflective film 400, the light or pressure may be transferred from the upper layers to the lower layers of the anti-reflective film 400 in the third direction DR3. By disposing a high-hardness material in the upper layers of the anti-reflective film 400, protection against external impacts can be effectively enhanced.

The hardness of an anti-reflective film 400 with oxynitride-contained high-refractive-index layers, i.e., the first and third refractive layers 410 and 430, in its upper part may be greater than the hardness of an anti-reflective film 400 with the oxynitride-contained high-refractive-index layers in its lower part.

At least one of the first and third refractive layers 410 and 430 may include an oxynitride, and the oxygen content of the oxynitride may be 10 at % or less.

The hardness of the first or third refractive layer 410 or 430 containing an oxynitride with an oxygen content of 10 at % or less may be greater than the hardness of a refractive layer containing a nitride not oxynitride.

Here, the oxynitride may include at least one of aluminum oxynitride, silicon oxynitride, aluminum-silicon oxynitride, germanium oxynitride, aluminum-germanium oxynitride, zirconium oxynitride, titanium oxynitride, and hafnium oxynitride.

In case that the oxynitride is aluminum oxynitride, silicon oxynitride, or aluminum-silicon oxynitride, the oxygen content in the oxynitride may be 5 at % or less.

In case that the oxynitride is aluminum-germanium oxynitride, the contents of aluminum, germanium, oxygen, and nitrogen in the aluminum-germanium oxynitride may satisfy the conditions in Equations 1 and 2 below:

$$0 < \frac{[ Ge ]}{[ Ge ] + [ Al ]} \leq 0 \text{.45} \qquad [ Equation 1 ]$$

$$0 < \frac{[ O ]}{[ O ] + [ N ]} \leq 0.3 \qquad [ Equation 2 ]$$

In Equations 2 and 3, [Ge], [Al], [O], and [N] represent the molar concentrations of germanium (Ge), Al, oxygen (O), and nitrogen (N), respectively.

Table 1 below shows the hardness and refractive index according to the contents of Al, GE, O, and N in each aluminum-germanium oxynitride.

TABLE 1

| | [Ge]/([Ge + | [O]/([O] + | Hardness | Refractive Index |
|---|---|---|---|---|
| No. | Al]) | [N]) | (GPa) | @633 nm |
| 1 | 0.30 | 0.0 | 17 ± 2 | 1.94 |
| 2 | 0.30 | 0.07 | 29 ± 2 | 2.01 |
| 3 | 0.28 | 0.08 | 28 ± 2 | 2.04 |
| 4 | 0.24 | 0.11 | 27 ± 3 | 1.96 |
| 5 | 0.22 | 0.32 | 16 ± 1 | 2.03 |
| 6 | 0.20 | 0.67 | 9.5 ± 0.5 | 1.99 |
| 7 | 0.19 | 0.85 | 7.7 ± 0.5 | — |
| 8 | 0.42 | 0.0 | 19 ± 3 | 2.14 |
| 9 | 0.37 | 0.04 | 21 ± 1 | 2.02 |
| 10 | 0.33 | 0.59 | 9.8 ± 0.2 | 2.04 |
| 11 | 0.35 | 0.82 | 8.9 ± 0.5 | 2.00 |
| 12 | 0.53 | 0.22 | 12 ± 0.6 | 2.16 |
| 13 | 0.57 | 0.29 | 11.5 ± 0.4 | 2.15 |
| 14 | 0.60 | 0.61 | 9.0 ± 0.5 | 2.11 |

Referring to Table 1, it can be observed that Nos. 2 through 4, 8, and 9, which satisfy both Equations 1 and 2, have a hardness of at least 20 GPa and a refractive index of at least 2.0. In contrast, Nos. 5 through 7, 10, and 11, which satisfy Equation 1 but not Equation 2, exhibit a refractive index of around 2.0 but a relatively lower hardness of 16 GPa or less. Notably, Nos. 6, 7, 10, and 11 have a hardness below 10 GPa, indicating that an increase in oxygen content within the oxynitride results in reduced hardness. Additionally, Nos. 12 through 14, which satisfy Equation 2 but not Equation 1, have a refractive index of at least 2.0 but a lower hardness of 15 GPa or less.

In the case of aluminum-germanium oxynitride, both Equations 1 and 2 need to be satisfied to achieve a hardness of at least 20 GPa and a refractive index of at least 2.0.

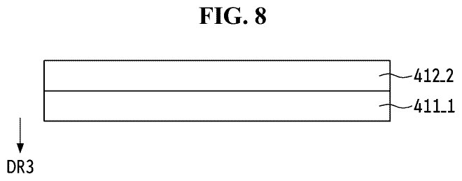

FIG. 8 is a cross-sectional view illustrating a first example of a refractive layer of the anti-reflective film in the display device according to an embodiment.

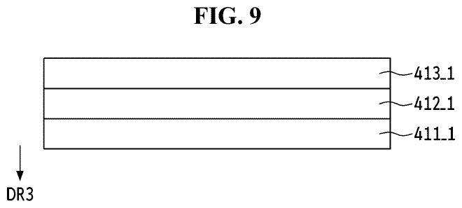

FIG. 9 is a cross-sectional view illustrating a second example of the refractive layer of the anti-reflective film in the display device according to an embodiment.

Referring to FIGS. 8 and 9, at least one of the first and third refractive layers 410 and 430 may include a first sub-layer 411_1, a second sub-layer 412_1, and a third sub-layer 413_1.

Specifically, at least one of the first and third refractive layers 410 and 430 may include a first sub-layer 411_1 containing an high-refractive-index material and a second sub-layer 412_1 located on the first sub-layer 411_1 and containing a oxynitride. In an embodiment, the high-refractive-index material in the second sub-layer 412_1 may be different from oxynitride. Furthermore, as illustrated in FIG. 9, at least one of the first and third refractive layers 410 and 430 may further include a third sub-layer 413_1 located on the second sub-layer 412_1 and also containing the high-refractive-index material.

In an embodiment, the high-refractive-index material may include aluminum oxynitride, silicon oxynitride, aluminum-silicon oxynitride, germanium oxynitride, aluminum-germanium oxynitride, zirconium oxynitride, titanium oxynitride, hafnium oxynitride, silicon nitride (Si₃N₄), aluminum nitride (AlN), zirconium nitride (ZrN), aluminum silicon nitride (AlSiN), chromium nitride (CrN), titanium nitride (TiN), manganese nitride (Mn₄N), iron nitride (FeNₓ), cobalt nitride (CoNₓ), Ni₃N, Cu₃N, zinc nitride (Zn₂N₃), vanadium nitride (VN), molybdenum nitride (Mo₂N), hafnium nitride (HfN), germanium nitride (Ge₃N₄), lead nitride (Pb(N₃)₂), titanium niobium oxide (Ti₄Nb₃O₃₅), titanium dioxide (TiO₂), zirconium dioxide (ZrO₂), lithium niobate (LiNbO₃), lithium tantalate (LiTaO₃), or lanthanum titanium oxide (LaTiO₂). However, the high-refractive-index material is not limited to these listed materials and may include any material suitable for achieving a high refractive index. The high-refractive-index material may have refractive index of 1.70 to 2.80.

FIGS. 8 and 9 illustrate at least one of the first and third refractive layers 410 and 430 as including the first, second, and third sub-layers 411_1, 412_1, and 413_1, but the present disclosure is not limited thereto. Alternatively, at least one of the first and third refractive layers 410 and 430 may further include a fourth sub-layer (not shown) located on an outer side of the second sub-layer 411_2 or on the third sub-layer 413_1.

At least one of the first and third refractive layers 410 and 430 may include a first sub-layer 411_1 containing an oxynitride, and second and third sub-layers 412_1 and 413_1 both containing the high-refractive-index material different from oxynitride. The hardness of the refractive layer where the first, second, and third sub-layers 411_1, 412_1, and 413_1 are stacked may be greater than the hardness of a single-layer refractive layer. This configuration may be adjusted as desirable based on the desired hardness, refractive index, and reflectance characteristics of the anti-reflective film 400.

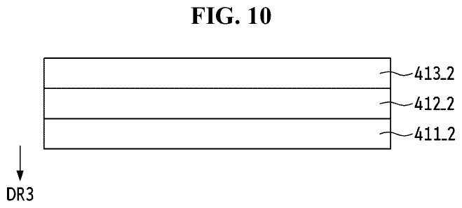

FIG. 10 is a cross-sectional view illustrating a third example of the refractive layer of the anti-reflective film in the display device according to an embodiment.

The example of FIG. 10 differs from the examples of FIGS. 8 and 9 in the materials of the sub-layers. The example of FIG. 10 will hereinafter be described, focusing mainly on the differences from the examples in FIGS. 8 and 9 and omitting redundant descriptions.

Referring to FIG. 10, at least one of the first and third refractive layers 410 and 430 may include a first sub-layer 411_2, a second sub-layer 412_2 located on the first sub-layer 411_2, and a third sub-layer 413_2 located on the second sub-layer 412_2.

The first and third sub-layers 411_2 and 413_2 may each independently include an oxide or a nitride. For example, the first sub-layer 411_2 may include an oxide, and the third sub-layer 413_2 may include a nitride. Alternatively, the first sub-layer 411_2 may include a nitride, and the third sub-layer 413_2 may include an oxide.

The second sub-layer 412_2 may include an oxynitride, and the oxygen content in the oxynitride may be 10 at % or less.

The first and third sub-layers 411_2 and 413_2 may independently include at least one element selected from Al, silicon (Si), Ge, zirconium (Zr), Ti, and hafnium (Hf). In an embodiment, the oxynitride of the second sub-layer 412_2 may include the elements present in the first and third sub-layers 411_2 and 413_2.

For example, in case that the first sub-layer 411_2 includes aluminum oxide and the third sub-layer 413_2 includes silicon nitride, the second sub-layer 412_2 may include aluminum-silicon oxynitride. The aluminum oxide of the first sub-layer 411_2 and the silicon nitride of the third sub-layer 413_2 may react between the first and third sub-layers 411_2 and 413_2, forming a second sub-layer 412_2 containing aluminum-silicon oxynitride.

Alternatively, the first sub-layer 411_2 containing aluminum nitride may be formed using an aluminum target under a nitrogen atmosphere. Thereafter, to form silicon oxide, oxygen may be added to the nitrogen atmosphere, and the aluminum target may be replaced with a silicon target. During this process, the remaining aluminum may react to form the second sub-layer 412_2 containing aluminum-silicon oxynitride. After all residual aluminum is used to form the second sub-layer 412_2, a third sub-layer 413_2 containing silicon oxide may be formed on the second sub-layer 412_2.

The first, second, and third sub-layers 411_2, 412_2, and 413_2 are illustrated as including aluminum oxide, aluminum-silicon oxynitride, and silicon nitride, respectively, but the present disclosure is not limited thereto. For another example, the first and third sub-layers 411_2 and 413_2 may be oxides or nitrides containing the aforementioned elements, and the second sub-layer 412_2 may be an oxynitride containing the elements included in the first and third sub-layers 411_2 and 413_2.

The following examples further describe the invention in detail. However, these examples are provided solely for illustrative purposes and are not intended to limit the scope of the present disclosure.

### 1. Fabrication of Anti-Reflective Films

Anti-reflective films according to Embodiments 1 through 3 and Comparative Examples 1 through 3 were fabricated as shown in Table 2 below.

In Embodiments 1 through 3, high-refractive-index layers corresponding to the upper layers (i.e., first and third refractive layers) of the anti-reflective films were fabricated using AlON, an oxynitride, with an oxygen content of 3 at %. In Comparative Examples 1 through 3, high-refractive-index layers corresponding to the lower layers of the anti-reflective films were fabricated using AlON with an oxygen content of 3 at %.

Low-refractive-index layers (i.e., second, fourth, sixth, eighth, tenth, and twelfth refractive layers) in Embodiments 1 through 3 were stacked using SiO₂ to the thicknesses specified in Table 2. The upper high-refractive-index layers (i.e., the first and third refractive layers) in Embodiments 1 through 3 were stacked using AlON with an oxygen content of 3 at % to the thicknesses specified in Table 2, and the remaining high-refractive-index layers (i.e., fifth, seventh, ninth, eleventh, and thirteenth refractive layers) were stacked using Si₃N₄ to the thicknesses specified in Table 2.

The low-refractive-index layers (i.e., the second, fourth, sixth, eighth, tenth, and twelfth refractive layers) in Comparative Examples 1 to 3 were stacked using SiO₂ to the thicknesses specified in Table 2.

In Comparative Example 1, the lower high-refractive-index layers (i.e., the seventh and ninth refractive layers) were stacked using AlON with an oxygen content of 3 at % to the thicknesses specified in Table 2, and the remaining high-refractive-index layers (i.e., the first, third and fifth refractive layers) were stacked using Si₃N₄ to the thicknesses specified in Table 2.

In Comparative Example 2, the lower high-refractive-index layers (i.e., the ninth and eleventh refractive layers) were stacked using AlON with an oxygen content of 3 at % to the thicknesses specified in Table 2, and the remaining high-refractive-index layers (i.e., the first, third, fifth and seventh refractive layers) were stacked using Si₃N₄ to the thicknesses specified in Table 2.

In Comparative Example 3, the lower high-refractive-index layers (i.e., the eleventh and thirteenth refractive layers) were stacked using AlON with an oxygen content of 3 at % to the 10 thicknesses specified in Table 2, and the remaining high-refractive-index layers (i.e., the first, third, fifth, seventh and ninth refractive layers) were stacked using Si₃N₄ to the thicknesses specified in Table 2.

TABLE 2

| | Configuration | | | | | |
|---|---|---|---|---|---|---|
| | | | | Low-Refractive-Index Layer: SiO₂ | | |
| | Low-Refractive-Index Layer: SiO₂ | | | Upper High-Refractive- Index Layer: Si₃N₄ | | |
| | Upper High-Refractive- Index Layer: AlON | | | Lower High-Refractive-Index Layer: AlON | | |
| Thickness | Lower High-Refractive-Index Layer: Si₃N₄ | | | Comparative | Comparative | Comparative |
| (nm) | Embodiment 1 | Embodiment 2 | Embodiment 3 | Example 1 | Example 2 | Example 3 |
| 1^{st} | 83 | 82.8 | 83 | 83 | 82.8 | 83 |
| Refractive | | | | | | |
| Layer | | | | | | |
| 2^{nd} | 144 | 163 | 153.5 | 144 | 163 | 153.5 |
| Refractive | | | | | | |
| Layer | | | | | | |
| 3^{rd} | 17 | 12.7 | 13.7 | 17 | 12.7 | 13.7 |
| Refractive | | | | | | |
| Layer | | | | | | |
| 4^{th} | 167 | 190 | 178 | 167 | 190 | 178 |
| Refractive | | | | | | |
| Layer | | | | | | |
| 5^{th} | 13.5 | 12.2 | 11 | 13.5 | 12.2 | 11 |
| Refractive | | | | | | |
| Layer | | | | | | |
| 6^{th} | 143 | 186.2 | 178.9 | 143 | 186.2 | 178.9 |
| Refractive | | | | | | |
| Layer | | | | | | |
| 7^{th} | 22.5 | 27.7 | 10 | 22.5 | 27.7 | 10 |
| Refractive | | | | | | |
| Layer | | | | | | |
| 8^{th} | 15 | 39.1 | 178 | 15 | 39.1 | 178 |
| Refractive | | | | | | |
| Layer | | | | | | |
| 9^{th} | 15 | 54.6 | 15 | 15 | 54.6 | 15 |
| Refractive | | | | | | |
| Layer | | | | | | |
| 10^{th} | | 22 | 156.9 | | 22 | 156.9 |
| Refractive | | | | | | |
| Layer | | | | | | |
| 11^{th} | | 20 | 34.8 | | 20 | 34.8 |
| Refractive | | | | | | |
| Layer | | | | | | |
| 12^{th} | | | 16.6 | | | 16.6 |
| Refractive | | | | | | |
| Layer | | | | | | |
| 13^{th} | | | 35.6 | | | 35.6 |
| Refractive | | | | | | |
| Layer | | | | | | |
| Total | 620 | 810 | 1065 | 620 | 810 | 1065 |
| Thickness | | | | | | |
| (nm) | | | | | | |
| High R.I. % | 76% | 74% | 81% | 76% | 74% | 81% |

In Table 2, “high R.I. %” represents the weight ratio of high-refractive-index material in each anti-reflective film.

Hereinafter, embodiments 4 through 6 are explained. Anti-reflective films were fabricated using AlSiON, with an oxygen content of 3 at %, as the high-refractive-index material instead of AlON. Specifically, referring to Table 3 below, anti-reflective films according to Embodiments 4 through 6 and Comparative Examples 4 through 7 were fabricated.

In Embodiments 4 through 6, high-refractive-index layers corresponding to the upper layers (i.e., the first and third refractive layers) of the anti-reflective films were fabricated using AlSiON, an oxynitride. In Comparative Examples 4 through 6, high-refractive-index layers corresponding to the lower layers of the anti-reflective films were fabricated using AlSiON, an oxynitride. Comparative Example 7 does not use an oxynitride as high-refractive-index layers.

Low-refractive-index layers (i.e., the second, fourth, sixth, eighth, tenth, and twelfth refractive layers) in Embodiments 4 through 6 were stacked using SiO₂ to the thicknesses specified in Table 3. The upper high-refractive-index layers (i.e., the first and third refractive layers) in Embodiments 4 through 6 were stacked using AlSiON with an oxygen content of 3 at % to the thicknesses specified in Table 3, and the remaining high-refractive-index layers (i.e., the fifth, seventh, ninth, eleventh, and thirteenth refractive layers) were stacked using Si₃N₄ to the thicknesses specified in Table 3.

Low-refractive-index layers (i.e., the second, fourth, sixth, eighth, tenth, and twelfth refractive layers) in Comparative Examples 4 through 7 were stacked using SiO₂ to the thicknesses specified in Table 3.

In Comparative Example 4, the lower high-refractive-index layers (i.e., the seventh and ninth refractive layers) were stacked using AlSiON with an oxygen content of 3 at % to the thicknesses specified in Table 3, and the remaining high-refractive-index layers (i.e., the first, third, and fifth refractive layers) were stacked using Si₃N₄ to the thicknesses specified in Table 3.

In Comparative Example 5, the lower high-refractive-index layers (i.e., the ninth and eleventh refractive layers) were stacked using AlSiON with an oxygen content of 3 at % to the thicknesses specified in Table 3, and the remaining high-refractive-index layers (i.e., the first, third, fifth and seventh refractive layers) were stacked using Si₃N₄ to the thicknesses specified in Table 3.

In Comparative Example 6, the lower high-refractive-index layers (i.e., the eleventh and thirteenth refractive layers) were stacked using AlSiON with an oxygen content of 3 at % to the thicknesses specified in Table 3, and the remaining high-refractive-index layers (i.e., the first, third, fifth, seventh and ninth refractive layers) were stacked using Si₃N₄ to the thicknesses specified in Table 3.

In Comparative Example 7, the high-refractive-index layers (i.e., the first, third, fifth, seventh, ninth, eleventh, and thirteenth refractive layers) were stacked using Si₃N₄ to the thicknesses specified in Table 3.

TABLE 3

| | Configuration | | | | | | |
|---|---|---|---|---|---|---|---|
| | | | | | | | Low- |
| | | | | | | | Refractive- |
| | | | | | | | Index |
| | | | | | | | Layer: |
| | | | | | | | SiO₂ |
| | | | | | | | High- |
| | | | | | | | Refractive- |
| | | | | Low-Refractive-Index Layer: SiO₂ | | | Index |
| | Low-Refractive-Index Layer: SiO₂ | | | Upper High-Refractive- Index Layer: Si₃N₄ | | | Layer: |
| | Upper High-Refractive- Index Layer: AlSiON | | | Lower High-Refractive-Index Layer: AlSiON | | | Si₃N₄ |
| Thickness | Lower High-Refractive-Index Layer: Si₃N₄ | | | Comparative | Comparative | Comparative | Comparative |
| (nm) | Embodiment 4 | Embodiment 5 | Embodiment 6 | Example 4 | Example 5 | Example 6 | Example 7 |
| 1^{st} | 85 | 86.1 | 81.7 | 85 | 86.1 | 81.7 | 84.8 |
| Refractive | | | | | | | |
| Layer | | | | | | | |
| 2^{nd} | 143.1 | 153.9 | 149 | 143.1 | 153.9 | 149 | 159.5 |
| Refractive | | | | | | | |
| Layer | | | | | | | |
| 3^{rd} | 14 | 12 | 15 | 14 | 12 | 15 | 14.5 |
| Refractive | | | | | | | |
| Layer | | | | | | | |
| 4^{th} | 175 | 181.5 | 173 | 175 | 181.5 | 173 | 186.7 |
| Refractive | | | | | | | |
| Layer | | | | | | | |
| 5^{th} | 10 | 12.4 | 10 | 10 | 12.4 | 10 | 10.1 |
| Refractive | | | | | | | |
| Layer | | | | | | | |
| 6^{th} | 49 | 190 | 173.5 | 49 | 190 | 173.5 | 182.6 |
| Refractive | | | | | | | |
| Layer | | | | | | | |
| 7^{th} | 40 | 25.9 | 12.5 | 40 | 25.9 | 12.5 | 10 |
| Refractive | | | | | | | |
| Layer | | | | | | | |
| 8^{th} | 18 | 29 | 174 | 18 | 29 | 174 | 174.6 |
| Refractive | | | | | | | |
| Layer | | | | | | | |
| 9^{th} | 85.9 | 65 | 12.3 | 85.9 | 65 | 12.3 | 13.9 |
| Refractive | | | | | | | |
| Layer | | | | | | | |
| 10^{th} | | 13.3 | 163.5 | | 13.3 | 163.5 | 156.9 |
| Refractive | | | | | | | |
| Layer | | | | | | | |
| 11^{th} | | 41 | 38 | | 41 | 38 | 34.8 |
| Refractive | | | | | | | |
| Layer | | | | | | | |
| 12^{th} | | | 17.5 | | | 17.5 | 16.6 |
| Refractive | | | | | | | |
| Layer | | | | | | | |
| 13^{th} | | | 45 | | | 45 | 35.6 |
| Refractive | | | | | | | |
| Layer | | | | | | | |
| Total | 620 | 810 | 1065 | 620 | 810 | 1065 | 1081 |
| Thickness | | | | | | | |
| (nm) | | | | | | | |
| High | 62% | 70% | 80% | 62% | 70% | 80% | 81% |
| R.I. % | | | | | | | |

In Table 3, “high R.I. %” represents the weight ratio of high-refractive-index material in each anti-reflective film.

### Evaluation

### 1. Hardness Measurement by Indentation Depth

Table 4 below shows the hardnesses of the anti-reflective films according to Embodiments 1 through 3 and Comparative Examples 1 through 3 and 7 for various indentation depths.

TABLE 4

| Indentation | Hardness (GPa) | | | | | | |
|---|---|---|---|---|---|---|---|
| Depth | | | | Comparative | Comparative | Comparative | Comparative |
| (nm) | Embodiment 1 | Embodiment 2 | Embodiment 3 | Example 1 | Example 2 | Example 3 | Example 7 |
| 50 | 16 | 16.2 | 16.6 | 15 | 15.2 | 15.1 | 15 |
| 100 | 19.3 | 19.6 | 20.2 | 18.2 | 18.3 | 18.3 | 18.2 |
| 150 | 18 | 19.3 | 21.9 | 17.4 | 18.4 | 20 | 19.9 |
| 200 | 16.2 | 17.4 | 20.5 | 15.8 | 16.7 | 18.8 | 18.7 |

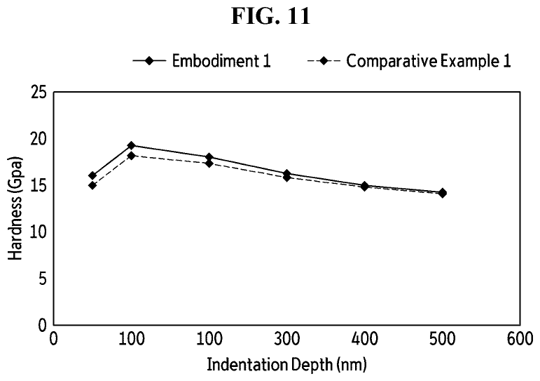

FIG. 11 is a graph showing the hardness (GPa) of Embodiment 1 and Comparative Example 1 as a function of indentation depth (nm).

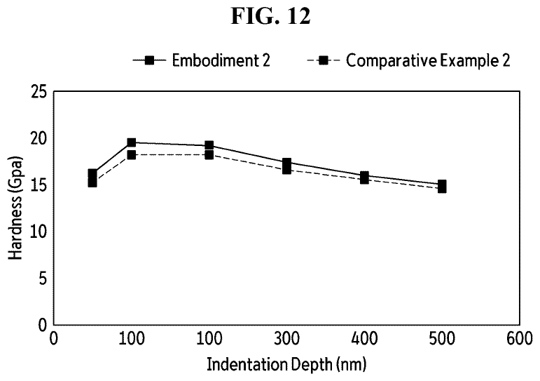

FIG. 12 is a graph showing the hardness (GPa) of Embodiment 2 and Comparative Example 2 as a function of indentation depth (nm).

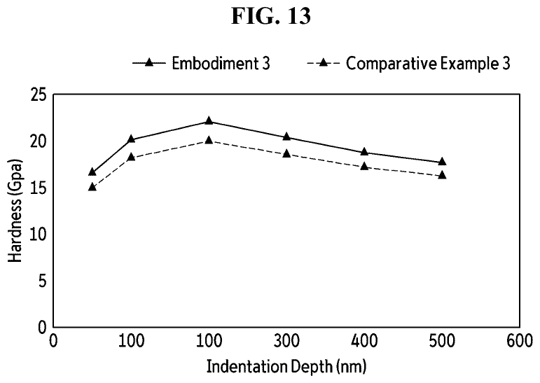

FIG. 13 is a graph showing the hardness (GPa) of Embodiment 3 and Comparative Example 3 as a function of indentation depth (nm).

According to the results shown in Table 4 and FIGS. 11 through 13, it can be observed that the indentation depth-dependent hardness of Embodiments 1 through 3, which use oxynitride for the second and fourth refractive layers (i.e., the upper layers) of the anti-reflective films, is greater than the indentation depth-dependent hardness of Comparative Examples 1 through 3, which use an oxynitride for the lower layers of the anti-reflective films.

Referring to FIG. 11, in case that comparing Embodiment 1 and Comparative Example 1, which have the same total thickness but differ only in the placement of the oxynitride-containing refractive layers, it can be observed that the hardness of Embodiment 1 is greater than the hardness of Comparative Example 1.

Referring to FIG. 12, in case that comparing Embodiment 2 and Comparative Example 2, which have the same total thickness but differ only in the placement of the oxynitride-containing refractive layers, it can be observed that the hardness of Embodiment 2 is greater than the hardness of Comparative Example 2.

Referring to FIG. 13, in case that comparing Embodiment 3 and Comparative Example 3, which have the same total thickness but differ only in the placement of the oxynitride-containing refractive layers, it can be observed that the hardness of Embodiment 3 is greater than the hardness of Comparative Example 3.

In case that an external force is applied, the upper layers of an anti-reflective film is the first to receive the impact. The applied force may transfer from the upper lowers to the lower layers of the anti-reflective film. If the upper layers of the anti-reflective film have sufficient hardness and durability, they can prevent the transmission of the external force from the upper layers to the lower layers. Conversely, if the hardness of the lower layers is greater than the hardness of the upper layers, it may be difficult to adequately prevent the transmission of force from the upper layers to the lower layers. Therefore, by disposing an oxynitride with greater hardness in the upper layers of the anti-reflective film, an anti-reflective film with improved hardness and durability can be achieved.

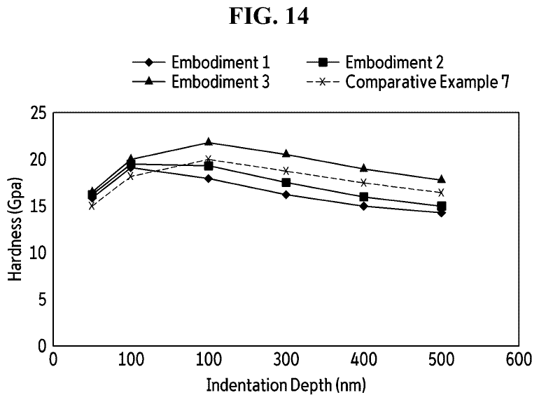

FIG. 14 is a graph showing the hardness (GPa) of Embodiments 1 through 3 and Comparative Example 7 as a function of indentation depth (nm).

Referring to Table 4 and FIG. 14, it can be observed that the hardness of Embodiment 3 is greater than the hardness of Comparative Example 7, despite their similar total thickness.

The hardness of a refractive layer containing an oxynitride with an oxygen content of 10 at % or less can be greater than the hardness of a refractive layer containing a nitride. In case that comparing Embodiment 3, Comparative Example 3, and Comparative Example 7, which have similar total thicknesses, it can be observed that Comparative Example 7, which uses Si₃N₄ as high-refractive-index layers, has the lowest hardness. Additionally, the hardness of Embodiment 3, which applies AlON with an oxygen content of 3 at % as upper layers, and Comparative Example 3, which applies AlON as lower layers, is greater than the hardness of Comparative Example 7. Generally, oxynitrides are known to have lower hardness, but by adjusting the oxygen content, oxynitrides with enhanced hardness can be obtained.

Compared to the formation of a nitride, the process control conditions for forming an oxynitride can be more relaxed. Consequently, in case that fabricating a refractive layer containing an oxynitride, process simplification and cost reduction can be achieved.

Table 5 below shows the hardnesses of the anti-reflective films according to Embodiments 4 through 6 and Comparative Examples 4 through 6 for various indentation depths.

TABLE 5

| Indentation | Hardness (GPa) | | | | | |
|---|---|---|---|---|---|---|
| Depth | | | | Comparative | Comparative | Comparative |
| (nm) | Embodiment 4 | Embodiment 5 | Embodiment 6 | Example 4 | Example 5 | Example 6 |
| 50 | 17.1 | 17.1 | 17.5 | 14.9 | 14.9 | 15.1 |
| 100 | 20.7 | 21.2 | 21.2 | 18 | 18.2 | 18.3 |
| 150 | 18 | 20.1 | 21.9 | 16.3 | 18.1 | 20.1 |
| 200 | 16 | 17.9 | 20 | 14.8 | 16.4 | 19 |

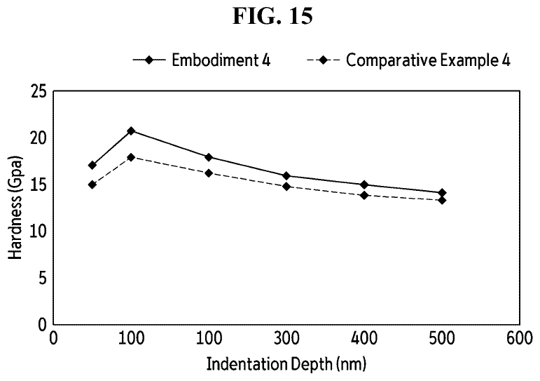

FIG. 15 is a graph showing the hardness (GPa) of Embodiment 4 and Comparative Example 4 as a function of indentation depth (nm).

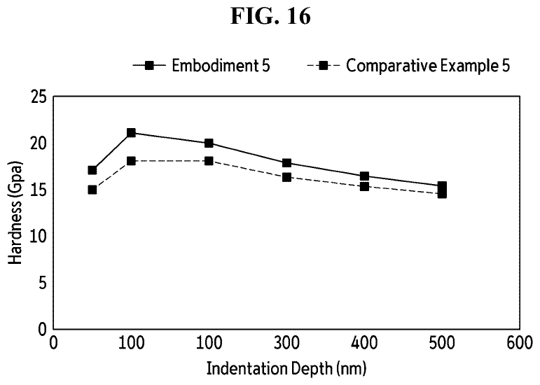

FIG. 16 is a graph showing the hardness (GPa) of Embodiment 5 and Comparative Example 5 as a function of indentation depth (nm).

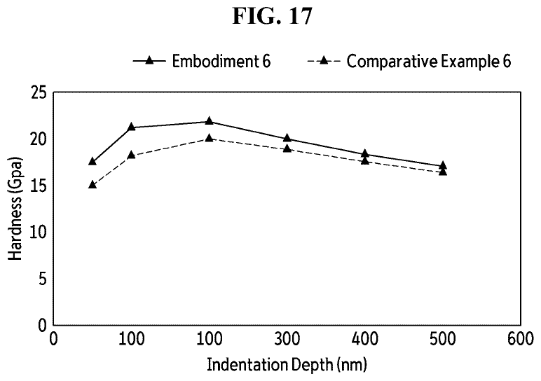

FIG. 17 is a graph showing the hardness (GPa) of Embodiment 6 and Comparative Example 6 as a function of indentation depth (nm).

According to the results shown in Table 5 and FIGS. 15 through 17, it can be observed that the indentation depth-dependent hardness of Embodiments 4 through 6, which use an oxynitride as the material for the second and fourth refractive layers (upper layers) of each anti-reflective film, is greater than the indentation depth-dependent hardness of Comparative Examples 4 through 6, which use an oxynitride for the lower layers of each anti-reflective film.

Referring to FIG. 15, in case that comparing Embodiment 4 and Comparative Example 4, which have the same total thickness but differ only in the placement of the oxynitride-containing refractive layers, it can be observed that the hardness of Embodiment 4 is greater than the hardness of Comparative Example 4.

Referring to FIG. 16, in case that comparing Embodiment 5 and Comparative Example 5, which have the same total thickness but differ only in the placement of the oxynitride-containing refractive layers, it can be observed that the hardness of Embodiment 5 is greater than the hardness of Comparative Example 5.

Referring to FIG. 17, in case that comparing Embodiment 6 and Comparative Example 6, which have the same total thickness but differ only in the placement of the oxynitride-containing refractive layers, it can be observed that the hardness of Embodiment 6 is greater than the hardness of Comparative Example 6.

Referring to Embodiments 1 through 6 and Comparative Examples 1 through 6, it can be confirmed that the hardness of the anti-reflective films with oxynitride-containing refractive layers having an oxygen content of 10 at % or less as upper layers is greater than the hardness of the anti-reflective film with such refractive layers as lower layers.

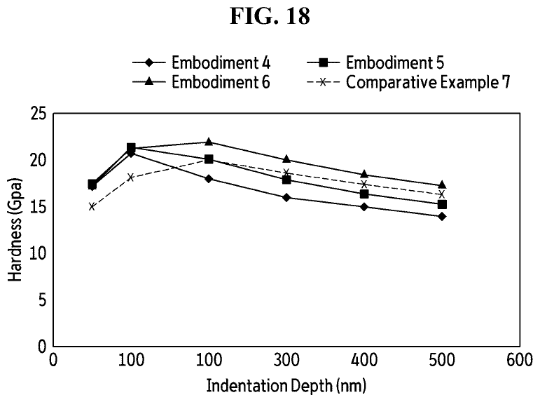

FIG. 18 is a graph showing the hardness (GPa) of Embodiments 4 through 6 and Comparative Example 7 as a function of indentation depth (nm).

Referring to Table 5 and FIG. 18, in case that comparing Embodiment 6 and Comparative Example 7, which have similar total thicknesses, it can be observed that the hardness of Embodiment 6 is greater than the hardness of Comparative Example 7. The hardness of Embodiment 6, which applies AlSiON with an oxygen content of 3 at % as upper layers, and Comparative Example 6, which applies AlSiON as lower layers, is also greater than the hardness of Comparative Example 7, which uses Si₃N₄ as high-refractive-index layers.

Referring to Embodiments 1 through 6 and Comparative Examples 1 through 7, it can be confirmed that the hardness of an anti-reflective film with refractive layers containing an oxynitride with an oxygen content of 10 at % or less either as upper layers or lower layers is greater than the hardness of an anti-reflective film composed only of refractive layers containing a nitride.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are examples in all respects and not restrictive.

What is claimed is:

1. An anti-reflective film comprising:
a base film;
a first refractive layer located on a first surface of the base film;
a second refractive layer located on the first refractive layer;
a third refractive layer located on the second refractive layer;
a fourth refractive layer located on the third refractive layer;
a fifth refractive layer located on the fourth refractive layer; and
a sixth refractive layer located on the fifth refractive layer,
wherein
a refractive index of the first refractive layer is greater than a refractive index of the second refractive layer,
a refractive index of the third refractive layer is greater than a refractive index of the fourth refractive layer,
a refractive index of the fifth refractive layer is greater than a refractive index of the sixth refractive layer,
light is incident from an outside on a second surface of the base film opposite to the first surface,
the first refractive layer or the third refractive layer comprises oxynitride, and
an oxygen content of the oxynitride is greater than 0 atomic percentage (at %) and equal to or less than 10 at %.

2. The anti-reflective film of claim 1, wherein the first refractive layer or the third refractive layer comprises: a second sub-layer containing oxynitride; and a first sub-layer located on the first sub-layer and containing a relatively high-refractive-index material except for oxynitride.

3. The anti-reflective film of claim 2, further comprising:
a third sub-layer located on the second sub-layer and containing a relatively high-refractive-index material except for oxynitride.

4. The anti-reflective film of claim 1, further comprising:
a seventh refractive layer located on the sixth refractive layer; and
an eighth refractive layer located on the seventh refractive layer,
wherein a refractive index of the seventh refractive layer is greater than a refractive index of the eighth refractive layer.

5. The anti-reflective film of claim 1, wherein the oxynitride comprises at least one of aluminum oxynitride, silicon oxynitride, aluminum-silicon oxynitride, germanium oxynitride, aluminum-germanium oxynitride, zirconium oxynitride, titanium oxynitride, and hafnium oxynitride.

6. The anti-reflective film of claim 5, wherein in case that the oxynitride is aluminum oxynitride, silicon oxynitride, or aluminum-silicon oxynitride, the oxygen content of the oxynitride is greater than 0 at % and equal to or less than 5 at %.

7. The anti-reflective film of claim 5, wherein in case that the oxynitride is aluminum-germanium oxynitride, contents of aluminum, germanium, oxygen, and nitrogen in the aluminum-germanium oxynitride satisfy Equations 1 and 2:
$$0 < \frac{[ Ge ]}{[ Ge ] + [ Al ]} \leq 0.45 ; \qquad [ Equation 1 ]$$
$$0 < \frac{[ O ]}{[ O ] + [ N ]} \leq 0.3 , \qquad [ Equation 2 ]$$
where [Ge], [Al], [O], and [N] represent molar concentrations of germanium, aluminum, oxygen, and nitrogen, respectively.

8. The anti-reflective film of claim 1, wherein
the anti-reflective film comprises a material with a refractive index of less than 1.6, and
a weight ratio of the material with a refractive index of less than 1.6 is greater than 0 weight percentage (wt %) and less than 35 wt % with respect to a total weight of the anti-reflective film.

9. The anti-reflective film of claim 1, wherein the anti-reflective film has a hardness of at least 20 gigapascals (GPa) in case that a thickness of the anti-reflective film is from 50 nanometers (nm) to 600 nm.

10. The anti-reflective film of claim 1, wherein the anti-reflective film has a hardness of at least 20 GPa in case that a thickness of the anti-reflective film is from 600 nm to 800 nm.

11. The anti-reflective film of claim 1, wherein the anti-reflective film has a hardness of at least 22 GPa in case that a thickness of the anti-reflective film is from 800 nm to 1,000 nm.

12. The anti-reflective film of claim 1, wherein
the first refractive layer or the third refractive layer comprises: a first sub-layer; a second sub-layer located on the first sub-layer; and a third sub-layer located on the second sub-layer,
the first and third sub-layers each independently comprise oxide or nitride,
the second sub-layer comprises oxynitride.

13. The anti-reflective film of claim 12, wherein the oxynitride comprises aluminum oxynitride, silicon oxynitride, aluminum-silicon oxynitride, germanium oxynitride, aluminum-germanium oxynitride, zirconium oxynitride, titanium oxynitride, or hafnium oxynitride.

14. The anti-reflective film of claim 13, wherein the first sub-layer and the third sub-layer each independently comprises at least one element selected from aluminum, silicon, germanium, zirconium, titanium, and hafnium, and the second sub-layer further comprises the elements present in both the first sub-layer and the third sub-layer.

15. The anti-reflective film of claim 12, wherein
the anti-reflective film comprises a material with a refractive index of less than 1.6, and
a weight ratio of the material with a refractive index of less than 1.6 is greater than 0 wt % and less than 35 wt % with respect to a total weight of the anti-reflective film.

16. The anti-reflective film of claim 12, wherein the anti-reflective film has a hardness of at least 20 GPa in case that a thickness of the anti-reflective film is from 50 nm to 600 nm.

17. A display device comprising:
a display panel;
an anti-reflective film located on the display panel; and
a window member located on the anti-reflective film,
wherein
the anti-reflective film comprises: a base film; a first refractive layer located on a first surface of the base film; a second refractive layer located on the first refractive layer; a third refractive layer located on the second refractive layer; a fourth refractive layer located on the third refractive layer; a fifth refractive layer located on the fourth refractive layer; and a sixth refractive layer located on the fifth refractive layer,
wherein a refractive index of the first refractive layer is greater than a refractive index of the second refractive layer,
a refractive index of the third refractive layer is greater than a refractive index of the fourth refractive layer,
a refractive index of the fifth refractive layer is greater than a refractive index of the sixth refractive layer,
the window member is located on a second surface of the base film opposite to the first surface,
the first refractive layer or the third refractive layer comprises oxynitride, and
an oxygen content of the oxynitride is greater than 0 at % and equal to or less than 10 at %.

18. The display device of claim 17, wherein the first refractive layer or the third refractive layer comprises: a second sub-layer containing oxynitride, and a first sub-layer located on the first sub-layer and containing a relatively high-refractive-index material except for oxynitride.

19. The display device of claim 17, wherein
the first refractive layer or the third refractive layer comprises: a first sub-layer; a second sub-layer located on the first sub-layer; and a third sub-layer located on the second sub-layer,
the first and third sub-layers each independently comprise oxide or nitride, and
the second sub-layer comprises oxynitride.

20. An electronic device comprising:
a display device for providing an image; and
a processor for transmitting an image data signal to the display device,
wherein the display device comprising:
a display panel;
an anti-reflective film located on the display panel; and
a window member located on the anti-reflective film,
wherein
the anti-reflective film comprises: a base film; a first refractive layer located on a first surface of the base film; a second refractive layer located on the first refractive layer; a third refractive layer located on the second refractive layer; a fourth refractive layer located on the third refractive layer; a fifth refractive layer located on the fourth refractive layer; and a sixth refractive layer located on the fifth refractive layer,
a refractive index of the first refractive layer is greater than a refractive index of the second refractive layer,
a refractive index of the third refractive layer is greater than a refractive index of the fourth refractive layer,
a refractive index of the fifth refractive layer is greater than a refractive index of the sixth refractive layer,
the window member is located on a second surface of the base film opposite to the first surface,
the first refractive layer or the third refractive layer comprises oxynitride, and
an oxygen content of the oxynitride is greater than 0 at % and equal to or less than 10 at %.
